(19) United States
(12) Patent Application Publication
(10) Pub. No.: US 2008/0174322 A1
(43) Pub. Date: Jul. 24, 2008

(54) Thin film resistance measurement method and tunnel magnetoresistive element fabrication method

(75) Inventor: Kenichi Kawai, Kawasaki (JP)

Correspondence Address: GREER, BURNS & CRAIN, 300 S WACKER DR, 25TH FLOOR, CHICAGO, IL, 60606, US

(73) Assignee: Fujitsu Limited, Kawasaki-shi (JP)

(21) Appl. No.: 11/985,740

(22) Filed: Nov. 16, 2007

(30) Foreign Application Priority Data
Jan. 19, 2007 (JP) 2007-010102

(51) Int. Cl. G01R 27/08; G11B 5/127

(52) U.S. Cl. 324/691; 29/603.09

(57) ABSTRACT

A method of measuring resistance of a tunnel magnetoresistive element having a first conductive layer, a resistive layer and a second conductive layer stacked on a substrate in this order. This magnetoresistive element has a pinned layer on one of the first and second low resistance layers, and a free layer on the other, and a barrier layer sandwiched between the pinned and free layers serving as the resistive layer. The method includes preparing a sample including in the following stacking order on the substrate a first low resistance layer having a low resistance, a thin film constituting the tunnel magnetoresistive element and having a constitution identical to the thin films formed of the first conductive, resistive, and second conductive layers and a second low resistance layer having a low resistance, and applying a resistance measurement probe to a surface of the sample to measure resistance of the thin film.

### BACKGROUND OF THE INVENTION

1. Field of the Invention

The present invention relates to a resistance measurement method which measures the resistance of a thin film formed on a substrate, such as a tunnel magnetoresistive element (TMR element), and a TMR element fabrication method which fabricates a high-performance TMR element using this resistance measurement method.

2. Description of the Related Art

Due to recent high-densification of hard disks, high-sensitivity and high-output magnetic heads are in demand. Tunnel magnetoresistive elements (TMR element) are receiving much attention for application as a magnetic head meeting this demand. This TMR element includes a thin low-resistance layer (Barrier Layer) known as the “Tunnel Barrier” sandwiched between a ferromagnetic layer known as the “Pinned Layer” and a ferromagnetic layer known as the “Free Layer”. The TMR element has a characteristic in which the electrical resistance (RA) of the element when the magnetizations of the pinned layer and the free layer are oriented anti-parallel differs from the electrical resistance (RA) of the element when the magnetizations of the pinned layer and the free layer are oriented in parallel. Utilizing such a characteristic, the element placed in close proximity of a hard disk detects the orientation of the magnetization of the free layer which changes according to the orientation of a magnetization recorded on the hard disk.

An example of a factor that largely influences performance of this TMR element is the electrical resistance (RA) of the barrier layer. Although this barrier layer is formed by depositing a film and oxidizing it, it is necessary to adjust deposition conditions and oxidation conditions of the barrier layer with high accuracy in order to manufacture a high-performance magnetic head since the electric resistance (RA) of this barrier layer is highly dependent upon the deposition conditions and the oxidation conditions. Accordingly, the deposition conditions and the oxidation conditions of the barrier layer of the TMR element to be used as a magnetic head for its fabrication is determined based on the measurement result for the electric resistances (RA) of the barrier layers of samples which is fabricated with a layered structure same as that of the TMR element to be used as a magnetic head.

FIG. 1 is a diagram that shows an example of a conventional sample structure including a layered structure as a TMR element for use in resistance measurement, and a resistance measurement method.

This sample 10 is formed by stacking in order on a Si substrate 11, a Ta layer 12, a Cu layer 13, a Ta layer 14, a seed layer 15, an antiferromagnetic layer 16, a pinned layer 17, a barrier layer 18, a free layer 19, a cap layer 20 and a surface cover layer 21. Out of these, the seed layer 15, the antiferromagnetic layer 16, the pinned layer 17, the barrier layer 18, the free layer 19, and the cap layer 20 constitute a TMR element 30 that acts as the TMR element. This TMR element 30 is divided into a first conductive layer 31 that is constituted by the seed layer 15, the antiferromagnetic layer 16 and the pinned layer 17, and a second conductive layer 32 that is constituted by the barrier layer 18, the free layer 19 and the cap layer 20.

Also, the Cu layer 13 causes the measurement of resistance of layers below the pin layer 17 to be lowered thereby enhancing the contribution of the barrier layer 18 to the resistance value of measurement, at the time of measurement of the electrical resistance (RA). The surface cover layer 21 acts to stabilize the resistance measurement by preventing oxidation of the surface of the TMR film 30. The Ta layer 12 and the Ta layer 14 are used for the separation of layers.

Here, resistance measurement is made with a plurality of resistance measurement probes 40 (four probes in FIG. 1) at a spacing of 1.5 μm to 35 μm for the resistance measurement deployed on the surface of the sample 10 having a stacked layered structure of the kind mentioned above, and calculation from the measurement value of the resistance provides the longitudinal electrical resistance (RA) of the TMR film 30.

“Magnetoresistance measurement of unpatterned magnetic tunnel junction wafers by current-in-plane tunneling” D.C. Worledge and P. L. Trouilloud, APPLIED PHYSICS LETTERS VOLUME 83. NUMBER 1, 7 Jul. 2003 describes a method for measuring resistance with the resistance measurement probe 40 applied to the surface.

Here, while it is possible to secure sufficient repetitious measurement accuracy in a case in which the resistance value of the barrier layer 18 is sufficiently high in comparison to the top and bottom layers, there exists a problem that it is necessary to adjust the resistance value of the barrier layer 18 of the TMR film 30 to the extremely low value of 0.1 to 10 Ωμm², typically a value of several Ωμm², and it is impossible to attain sufficient measurement accuracy with the measurement method of FIG. 1.

In order to solve this problem and execute resistance measurement of a sufficiently high accuracy, it is necessary to form terminals on the bottom portion and the top portion of the TMR film for the purpose of electrical resistance measurement by a TEG (Test Element Guide) process after having executed TMR film production, create a state of the TMR film being sandwiched electrically from above and below, and execute measurement of the electrical resistance between the terminals (See Japanese Patent Laid-Open No. 2001-23131). Usually, it is necessary to adjust the film formation conditions and the oxidation conditions of the barrier layer while repeatedly conducting film formation and resistance measurement of the TMR film numerous times. A TEG process of the kind mentioned above, if required, takes 3 to 4 days for the TEG process to complete a single run, and therefore, if the process steps of the film formation process and the TEG process are repeated while the measured resistance values are fed back to re-adjust the film formation conditions and the oxidation conditions, the result is a need for a great amount of time for the setting of the conditions.

### SUMMARY OF THE INVENTION

The present invention has been made in view of the above circumstances and provides a thin film resistance measurement method to easily and precisely measure the electrical resistance of a thin film on a substrate, and a tunnel magnetoresistive element fabrication method of fabricating a TMR element (tunnel magnetoresistive element) of which resistance value has been adjusted at high accuracy using the thin film resistance measurement method.

The thin film resistance measurement method of the present invention is a thin film resistance measurement method that measures resistance of a thin film including a first conductive layer, a resistive layer and a second conductive layer stacked on a substrate in this order, the method including:

a sample preparation step of preparing a sample including in the following staking order on the substrate a first low resistance layer that has a resistance value lower than a resistance value of either of the first conductive layer and the second conductive layer, the thin film, and a second low resistance layer that has a resistance value lower than a resistance value of either of the first conductive layer and the second conductive layer, and

a resistance measurement step of applying a resistance measurement probe to a surface of the sample to measure resistance of the thin film.

According to the thin film resistance measurement method of the present invention, since there is a low resistance layer above and below the thin film, it is possible to use the measurement method of the kind shown in FIG. 1 that applies a resistance measurement probe to the surface and improves the accuracy in measurement of resistance value of the thin film, and thus it is possible to conduct a resistance measurement with ease and with high accuracy.

Here, in the thin film resistance measurement method of the present invention, it is preferable that the sample preparation step is a step of preparing the sample further including a surface cover layer (such as a layer for preventing oxidation) stacked on the second low resistance layer, and the resistance measurement step is a step of applying a resistance measurement probe to a surface of the surface cover layer to measure the resistance value of the thin film.

If the surface cover layer is provided, a more stable resistance measurement becomes possible.

It is preferable to use for the surface cover layer a material that is difficult to oxidize and contains as its main component any of Ru, Ag, Au, Pt and the like, for example.

Also, it is preferable that the sample preparation step is a step of preparing the sample in which the first low resistance layer and the second low resistance layer are both Cu layers.

Such forming layers of Cu material as the first low resistance layer and the second low resistance layer can provide a layer having a resistance value that is sufficiently low.

Also, it is preferable that the sample preparation step is a step of preparing the sample further including a Ta layer stacked between the first low resistance layer and the thin film.

Such forming the Ta layer can prevent the formation of the Cu layer from affecting the thin film.

Also, it is preferable that the sample preparation step is a step of stacking the first low resistance layer after applying a planarization treatment to a layer below the first low resistance layer.

Such planarization treatment to the layer below the first low resistance layer can also planarize the first low resistance layer and further improve the measurement accuracy.

Also, it is preferable that the sample preparation step is a step of preparing the sample in which the first low resistance layer and the second low resistance layer are both layers of material having a specific resistance lower than the specific resistance of material forming the first conductive layer and the second conductive layer.

Although description has been given of the first low resistance layer and the second low resistance layer having Cu as their material, it is not necessary that the first low resistance layer and the second low resistance layer are layers having Cu as material, as these layers may be formed of, for example, Ag, Au, Pt or the like, which are materials of low specific resistance.

Also, it is preferable that the resistive layer is formed of an oxide insulation material or the like containing any of Ti, Mg, Al and the like as the main component.

Furthermore, it is preferable that the sample preparation step is a step of preparing the sample in which the resistive layer has an electrical resistance (RA) of 0.1 Ωμm² to 10 Ωμm².

The thin film resistance measurement method of the present invention is well suited to measurement of this degree of electrical resistance.

Also, the sample preparation step may be a step of preparing the sample in which a magnetic layer is included in at least one of the first conductive layer and the second conductive layer. Typically, the sample preparation step may be a step of preparing the sample of a tunnel magnetoresistive element that includes a pinned layer on one of the first conductive layer and the second conductive layer, and a free layer on the other of the first conductive layer and the second conductive layer, and a barrier layer sandwiched between the pinned layer and the free layer may serve as the resistive layer.

The thin film resistance measurement method of the present invention is used suitably in the resistance measurement of thin films in which magnetic materials, such as TMR elements, are used.

Also, the present invention provides a method of fabricating a tunnel magnetoresistive element including a first conductive layer, a resistive layer and a second conductive layer stacked on a substrate in this order, wherein there is a pinned layer on one of the first conductive layer and the second conductive layer, and a free layer on the other of the first conductive layer and the second conductive layer, and a barrier layer sandwiched between the pinned layer and the free layer serves as the resistive layer, the method including:

a thin film resistance measurement step of preparing a sample including in the following stacking order on the substrate a first low resistance layer having a resistance value lower than a resistance value of either the first conductive layer and the second conductive layer, a thin film constituting the tunnel magnetoresistive element and having a constitution identical to the thin films formed of the first conductive layer, the resistive layer and the second conductive layer, and a second low resistance layer having a resistance value lower than a resistance value of either the first conductive layer and the second conductive layer, and applying a resistance measurement probe to a surface of the sample to measure resistance of the thin film,

a condition adjustment step of adjusting formation conditions of the resistive layer based on the resistance value of the thin film measured in the thin film resistance measurement step, and

a fabrication step of fabricating a tunnel magnetoresistive element under conditions adjusted by the condition adjustment step.

Here, in the method of fabricating a tunnel magnetoresistive element of the present invention, the condition adjustment step may be a step of adjusting film formation conditions of the resistive layer, or the condition adjustment step may be a step of adjusting oxidation conditions of the resistive layer.

According to the method of fabricating a tunnel magnetoresistive element of the present invention, it is possible to measure the resistance value of the thin film with ease and high accuracy, adjust fabrication conditions with ease and high accuracy, and fabricate a high accuracy tunnel magnetoresistive element.

As mentioned in the description above, according to the present invention, it is possible to measure the resistance value of a film such as a TMR element with ease and high accuracy.

### BRIEF DESCRIPTION OF THE DRAWINGS

FIG. 1 is a diagram showing an example of a conventional sample structure including a layered structure as a TMR element for use in resistance measurement, and a resistance measurement method;

FIG. 2 is a diagram of one exemplary layered structure of a measurement sample and the resistance measurement method used in the present invention;

FIG. 3 is a graph showing the relationship between resistance measurement accuracies and thicknesses of Cu layer underneath a TMR film shown in FIG. 2;

FIG. 4 is a graph showing the relationship between resistance measurement accuracies and thicknesses of Cu layer above a TMR film shown in FIG. 2; and

FIG. 5 is a flowchart showing an example of a tunnel magnetoresistive element fabrication method of the present invention.

### DETAILED DESCRIPTION OF THE INVENTION

Herein below, an exemplary embodiment of the present invention will be described.

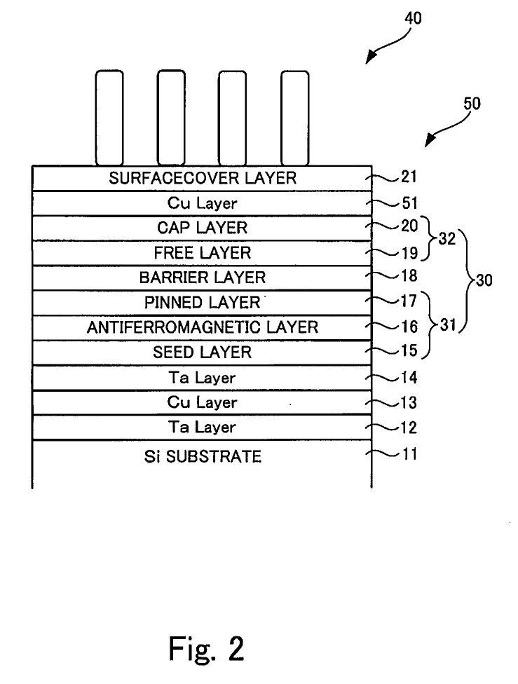

FIG. 2 is a diagram of one exemplary layered structure of a measurement sample and a resistance measurement method used in the present invention.

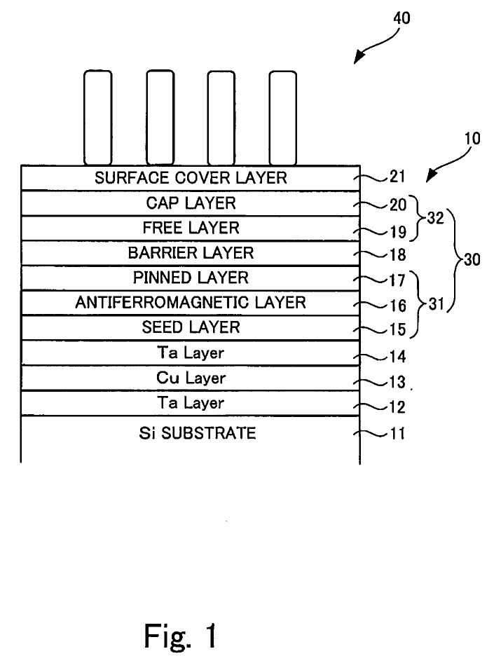

In FIG. 2, the same symbols are given to structure layers identical to those in FIG. 1, and description is given to what differs from the conventional example shown in FIG. 1 and what was omitted in the description of FIG. 1.

What mainly differs in FIG. 2 from the conventional example of FIG. 1 is that a Cu layer 51 is formed between the TMR film 30 and the surface cover layer 21. Here, the TMR film 30 is sandwiched between the Cu layer 51 and the Cu layer 13 located below the TMR film 30. Sandwiching the TMR film 30 with the Cu layer 51 and the Cu layer 13 having low resistance in this manner results in that the resistance value of the TMR film 30 becomes relatively higher than those of layers above and below the TMR film 30 thereby achieving high-accuracy measurement even when the resistance measurement probe 40 is applied to the surface, and providing measurement with ease and high-accuracy.

Here, the Cu layer 13 below the TMR film 30 is planarized to a flatness (Ra) of 1 nm or less. And in conducting this planarizing, a planarization treatment is applied to the Ta layer 12 located underneath the Cu layer 13, so that the Cu layer 13, which is stacked atop the flattened Ta layer 12, becomes flat. It is possible to use CMP (Chemical Mechanical Polishing), GCIB (Gas Cluster Ion Beam), or the like for the application of the planarization treatment to the Ta layer 12.

Also, the surface cover layer is composed of a material that is difficult to oxidize and contains Ru, Ag, Au, Pt or the like as its main component, thereby preventing oxidation of the TMR film 30.

Moreover, the barrier layer 18 is composed of an oxide insulation material that contains Ti, Mg, Al or the like as its main component, and its electrical resistance (RA) is adjusted to any value within 0.1 Ωμm² to 10 Ωμm².

Also, it is preferable that the Cu layer 13 below the TMR film 30 is of a film thickness of 40 nm to 100 nm. It is preferable that the Ta layer 14 above the Cu layer 13 is of a film thickness of 1 nm to 30 nm. It is preferable that the Cu layer 51 above the TMR layer 30 is of a film thickness of 2 nm to 50 nm.

Although, in the example shown in FIG. 2, the Cu layer 13 and the Cu layer 51 are used as low resistance layers sandwiching the TMR film 30 from above and below, such low resistance layers may be composed of, instead of Cu layer, a material of a low specific resistance that contains Ag, Au, Pt or the like as its main component.

Table 1 is a table listing resistance values and the measurement accuracies of the conventional sample (Comparative Example) shown in FIG. 1 and the sample of the embodiment (Example of the invention) shown in FIG. 2.

Table 1 shows average values and standard deviations (σ)/average value from 10 executions of measurement of a common point of each sample.

From Table 1, it can be seen that Example of the invention has extremely high measurement accuracy. In particular, in the case of Conventional Example, measurement of the resistance value at 1.5 Ωμm² or less was impossible, but in Example of the invention, even a resistance value of this degree was measured with sufficient measurement accuracy.

TABLE 1

| | Example of the invention | | | Comparative Example | |
|---|---|---|---|---|---|
| Ra Average | 1.43 | 2.62 | 3.74 | 2.66 | 3.06 |
| Value (Ωμm²) | | | | | |
| Ra Measurement | 3.7% | 2.0% | 1.7% | 55.6% | 9.8% |
| Accuracy σ/ | | | | | |
| Average Value | | | | | |

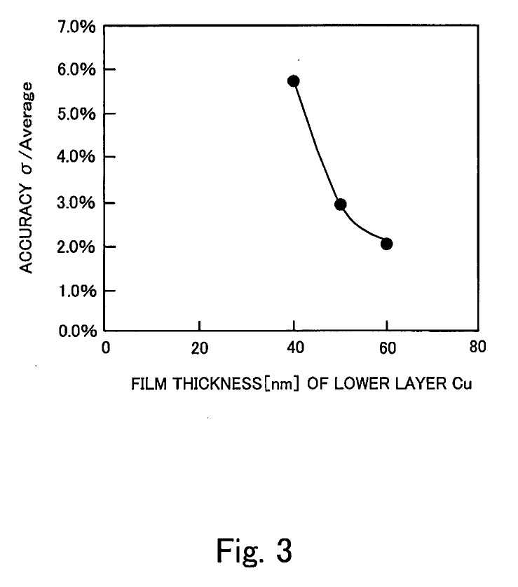

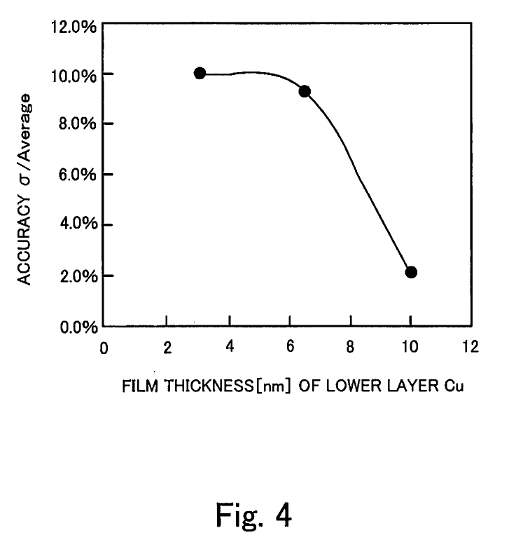

FIG. 3 is a graph showing the relationship between the resistance measurement accuracy and the thickness of the Cu layer 13 underneath the TMR film 30 shown in FIG. 2. FIG. 4 is a graph showing the relationship between the resistance measurement accuracy and the thickness of the Cu layer 51 above the TMR film 30 shown in FIG. 2.

Here, both FIG. 3 and FIG. 4 employ the standard deviation (σ)/average value (Average) from 10 executions of measurement of a common point in a case of RA=3 Ωμm².

In this manner, since the resistance measurement accuracy differs depending on the thickness of the Cu layer 13 and the Cu layer 51, it is preferable to select a suitable thickness for each of the Cu layer 13 and the Cu layer 51 in the preparation of the sample.

Note that FIG. 2 shows a sample for resistance measurement, while a TMR element to be used for an actual magnetic head is fabricated without layers that are unnecessary to provide the characteristic of the TMR element, such as Cu layers. Specifically, for example, a shield layer is stacked instead of the Cu layer 13, and stacking of the Cu layer 51 and the surface cover layer 21 is omitted. However, a common single fabrication process may be used to fabricate both the TMR element to be used for an actual magnetic head and the sample for resistance measurement in a manner that a TMR element is produced in which a low resistance layer is provided as a shield layer instead of the Cu layer 13 and the Cu layer 51 and the surface cover layer 21 are stacked, and then the Cu layer 51 and the surface cover layer 21 are eliminated in subsequent processes.

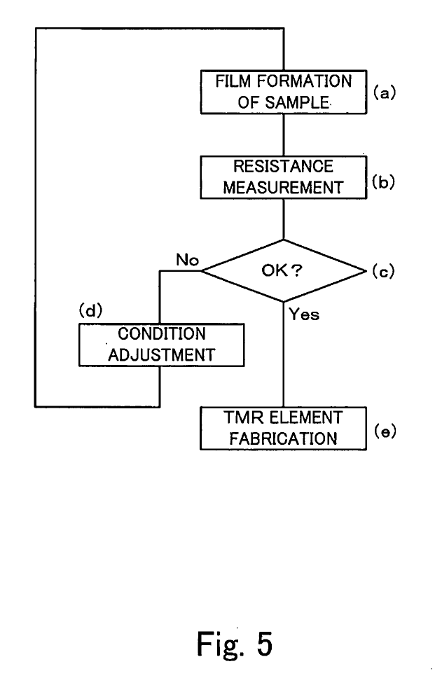

FIG. 5 is a flowchart showing an example of the tunnel magnetoresistive element fabrication method of the present invention.

In a step (a), the film formation of the sample and having a layered structure shown in FIG. 2 is conducted. In a step (b), a resistance measurement probe is applied to the surface of this sample to conduct resistance measurement. Determination is then made as to whether or not the measured resistance value falls within a predetermined range (step (c)), and if the measured resistance value does not fall within the predetermined range, film formation conditions (film thickness or the like) for the barrier layer 18 and oxidation conditions (oxidative gas pressure, oxidation time period or the like) are adjusted (step (d)), and film formation of the next sample is conducted under the adjusted conditions (step (a)). Through repeating of the steps (a) through (d), if the measured resistance value falls within the predetermined range in the step (c), then a TMR element is fabricated under the latest conditions, for use in, for example, the magnetic head of a hard disc drive (step (e)).

Note that the method in FIG. 5 also includes an embodiment of the thin film resistance measurement method consisting of the steps (a) and (b) according to the present invention.

What is claimed is:

1. A thin film resistance measurement method that measures resistance of a thin film comprising a first conductive layer, a resistive layer and a second conductive layer stacked on a substrate in this order, the method comprising:
a sample preparation step of preparing a sample comprising in the following stacking order on the substrate a first low resistance layer that has a resistance value lower than a resistance value of either of the first conductive layer and the second conductive layer, the thin film, and a second low resistance layer that has a resistance value lower than a resistance value of either of the first conductive layer and the second conductive layer; and
a resistance measurement step of applying a resistance measurement probe to a surface of the sample to measure resistance of the thin film.

2. The thin film resistance measurement method according to claim 1, wherein the sample preparation step is a step of preparing the sample further comprising a surface cover layer stacked on the second low resistance layer, and the resistance measurement step is a step of applying a resistance measurement probe to a surface of the surface cover layer to measure the resistance value of the thin film.

3. The thin film resistance measurement method according to claim 1, wherein the sample preparation step is a step of preparing the sample in which the first low resistance layer and the second low resistance layer are both Cu layers.

4. The thin film resistance measurement method according to claim 3, wherein the sample preparation step is a step of preparing the sample further comprising a Ta layer stacked between the first low resistance layer and the thin film.

5. The thin film resistance measurement method according to claim 4, wherein the sample preparation step is a step of stacking the first low resistance layer after applying a planarization treatment to a layer under the first low resistance layer.

6. The thin film resistance measurement method according to claim 1, wherein the sample preparation step is a step of preparing the sample in which the first low resistance layer and the second low resistance layer are both layers of material having a specific resistance lower than specific resistances of material forming the first conductive layer and the second conductive layer.

7. The thin film resistance measurement method according to claim 1, wherein the sample preparation step is a step of preparing the sample in which the surface cover layer is an oxidation preventive layer.

8. The thin film resistance measurement method according to claim 1, wherein the sample preparation step is a step of preparing the sample in which the resistive layer is a layer of insulation material.

9. The thin film resistance measurement method according to claim 1, wherein the sample preparation step is a step of preparing the sample in which the resistive layer has an electrical resistance (RA) of 0.1 Ωμm² to 10 Ωμm².

10. The thin film resistance measurement method according to claim 1, wherein the sample preparation step is a step of preparing the sample in which a magnetic layer is included in at least one of the first conductive layer and the second conductive layer.

11. The thin film resistance measurement method according to claim 1, wherein the sample preparation step is a step of preparing the sample of a tunnel magnetoresistive element that includes a pinned layer in one of the first conductive layer and the second conductive layer, and a free layer on the other of the first conductive layer and the second conductive layer, and a barrier layer sandwiched between the pinned layer and the free layer serves as the resistive layer.

12. A method of fabricating a tunnel magnetoresistive element comprising a first conductive layer, a resistive layer and a second conductive layer stacked in a substrate in this order, wherein there is a pinned layer on one of the first conductive layer and the second conductive layer, and a free layer in the other of the first conductive layer and the second conductive layer, and a barrier layer sandwiched between the pinned layer and the free layer serves as the resistive layer, the method comprising:
a thin film resistance measurement step of preparing a sample comprising in the following stacking order on the substrate a first low resistance layer having a resistance value lower than a resistance value of either the first conductive layer and the second conductive layer, a thin film constituting the tunnel magnetoresistive element and having a constitution identical to the thin films formed of the first conductive layer, the resistive layer and the second conductive layer, and a second low resistance layer having a resistance value lower than a resistance value of either the first conductive layer and the second conductive layer, and applying a resistance measurement probe to a surface of the sample to measure resistance of the thin film;
a condition adjustment step of adjusting a formation condition of the resistive layer based on the resistance value of the thin film measured in the thin film resistance measurement step; and
a fabrication step of fabricating the tunnel magnetoresistive element under a condition adjusted by the condition adjustment step.

13. The method of fabricating a tunnel magnetoresistive element according to claim 12, wherein the condition adjustment step is a step of adjusting a film formation condition of the resistive layer.

14. The method of fabricating a tunnel magnetoresistive element according to claim 12, wherein the condition adjustment step is a step of adjusting an oxidation condition of the resistive layer.
